(19) United States
(12) Patent Application Publication
(10) Pub. No.: US 2014/0367147 A1
(43) Pub. Date: Dec. 18, 2014

(54) INSULATING RESIN COMPOSITION FOR PRINTED CIRCUIT BOARD, INSULATING FILM, PREPREG AND PRINTED CIRCUIT BOARD

(71) Applicant: Samsung Electro-Mechanics Co., Ltd., Suwon-si (KR)

(72) Inventors: Jin Seok Moon, Suwon-si (KR); Hyun Jun Lee, Suwon-si (KR); Seong Hyun Yoo, Suwon-si (KR); Jin Young Klm, Suwon-si (KR); Geum Hee Yun, Suwon-si (KR)

(73) Assignee: Samsung Electro-Mechanics Co., Ltd., Suwon-si (KR)

(21) Appl. No.: 14/172,242

(22) Filed: Feb. 4, 2014

(30) Foreign Application Priority Data
Jun. 17, 2013 (KR) 10-2013-0069184

(51) Int. Cl. H05K 1/03; H05K 1/02

(52) U.S. Cl. CPC H05K 1/0373; H05K 1/0353; H05K 1/0298
USPC 174/251; 525/438; 523/400; 523/466

(57) ABSTRACT

Disclosed herein are an insulating resin composition for a printed circuit board, an insulating film, a prepreg, and a printed circuit board. More specifically, disclosed herein are an insulating resin composition for a printed circuit board including a maleimide resin having three or more maleimide groups, and the like so that a glass transition temperature and a mechanical strength are improved, an insulating film and a prepreg prepared using the insulating resin composition, and a printed circuit board including the insulating film or the prepreg.

### CROSS REFERENCE TO RELATED APPLICATION

This application claims the benefit of Korean Patent Application No. 10-2013-0069184, filed on Jun. 17, 2013, entitled “Insulating Resin Composition for Printed Circuit Board, Insulating Film, Prepreg, and Printed Circuit Board” which is hereby incorporated by reference in its entirety into this application.

### BACKGROUND OF THE INVENTION

1. Technical Field

The present invention relates to an insulating resin composition for a printed circuit board, an insulating film, a prepreg, and a printed circuit board.

2. Description of the Related Art

With the development of electronic equipment, printed circuit boards may have been lighter, thinner, and smaller. In order to meet the needs, wirings of printed circuits have become complicated and highly integrated. Hence, electric, thermal, and mechanical properties, which have been required for such printed circuit boards, serve as important factors. The printed circuit boards are configured of copper serving as circuit wirings and polymer serving as an interlayer insulation layer. Compared to the copper, the polymer forming the insulating layer requires several properties such as a coefficient of thermal expansion, a glass transition temperature, and thickness uniformity, and particularly is required to make an insulating layer thin.

As circuit boards become thinner, the circuit boards have less rigidity, and thus defects may occur due to a warpage phenomenon when components are mounted thereon at a high temperature. In order to solve these problems, heat resistance and thermal expansion properties of a thermosetting polymer resin serve as important factors, which may be closely affected by a polymer structure at the time of thermosetting, and a curing density and a network between polymer chains forming a board composition.

An existing liquid crystal oligomer and a liquid crystal oligomer as a board-forming composition containing an epoxy-based resin are an oligomer having liquid crystal properties with hydroxyl groups introduced at both ends. Herein, the epoxy-based resin is an N,N,N′,N′-tetraglycidyl-4,4′-methylenebisbenzenamine having four functional groups. The liquid crystal oligomer and the epoxy-based resin are blended with an N,N′-dimethyl acetamide (DMAc) along with dicyandiamide at a specific blending ratio to form a composition. In order that the epoxy-based resin is allowed to be cured with the liquid crystal oligomer having a hydroxyl group in this composition, the epoxy-based resin, an N,N,N′N′-tetraglycidyl-4,4′-methylenebisbenzenamine should be added thereto, followed by thermosetting. At this time, this composition has flexibility of the epoxy-based resin molecular chains and a hydroxyl group prepared by reaction with the poly-functional epoxy resin. Therefore, this composition is not suitable for a higher glass transition temperature (Tg) and a lower coefficient of thermal expansion (CIE), which are important for material properties of circuit boards.

On the other hand, Patent Document 1 discloses a thermosetting composition including a liquid crystal oligomer, a bismaleimide-based compound, an epoxy compound, and fluorine-based polymer resin powder, however, a sufficient mutual network between the compositions may not be formed, and thus there is a problem that a glass transition temperature suitable for a printed circuit board may not be implemented.

### PRIOR ART DOCUMENT

### Patent Document

(Patent Document 1) Korean Patent Laid-Open Publication No. 2011-0108782

### SUMMARY OF THE INVENTION

It is confirmed that an insulating resin composition for a printed circuit board including a maleimide resin having three or more maleimide groups, a liquid crystal oligomer, and an epoxy resin, and a product prepared by using the resin composition, may improve a glass transition temperature and mechanical strength properties. Thus, the present invention was completed based thereon.

Therefore, the present invention has been made in an effort to provide an insulating resin composition for a printed circuit board in which a glass transition temperature and a mechanical strength are improved.

Further, the present invention has been made in an effort to provide an insulating film prepared by the insulating resin composition.

Further, the present invention has been made in an effort to provide a prepreg prepared by the insulating resin composition.

Further, the present invention has been made in an effort to provide a printed circuit board provided with the insulating film.

Further, the present invention has been made in an effort to provide a multilayer printed circuit board provided with the prepreg.

According to a preferred embodiment of the present invention, there is provided an insulating resin composition for a printed circuit board, including: a maleimide resin having three or more maleimide groups; a liquid crystal oligomer; and an epoxy resin.

The insulating resin composition may further include an inorganic filler.

A content of the maleimide resin may be 10 to 40 wt %, a content of the liquid crystal oligomer may be 30 to 60 wt %, and a content of the epoxy resin may be 30 to 60 wt %, based on 100 parts by weight of the resin composition.

A content of the maleimide resin may be 5 to 20 wt %, a content of the liquid crystal oligomer may be 10 to 30 wt %, and a content of the inorganic filler may be 50 to 80 wt %, based on 100 parts by weight of the resin composition.

The maleimide resin may be an oligomer of phenyl methane maleimide represented by the following Formula 1.

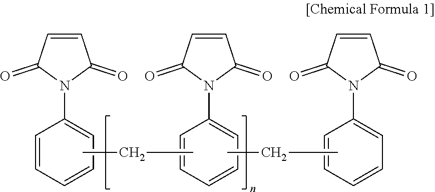

Herein, n is an integer of 1 or 2.

The liquid crystal oligomer may be represented by the following Formula 2.

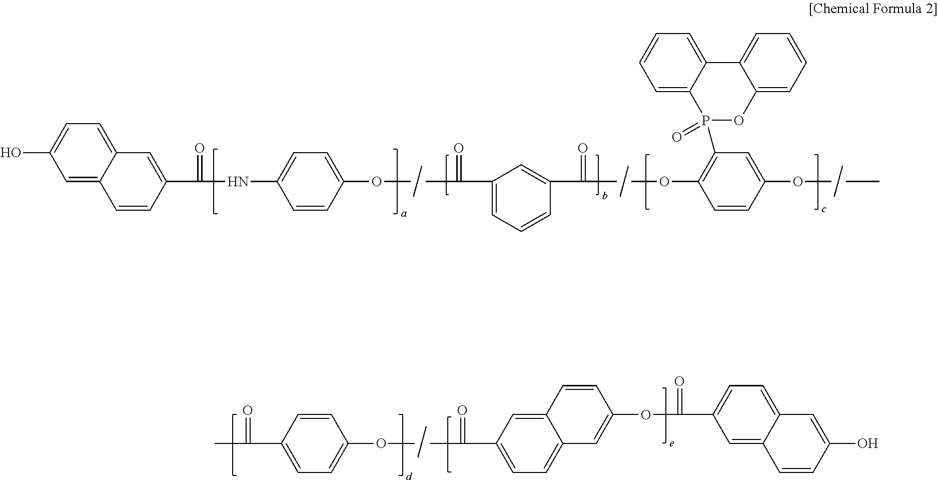

Herein, a is an integer of 13 to 26, b is an integer of 13 to 26, c is an integer of 9 to 21, d is an integer of 10 to 30, and e is an integer of 10 to 30.

The epoxy resin may be at least one selected from a group consisting of a naphthalene-based epoxy resin, a bisphenol A type epoxy resin, a phenol novolac epoxy resin, a cresol novolac epoxy resin, a rubber modified epoxy resin, a phosphorus-based epoxy resin, and a bisphenol F type epoxy resin.

The inorganic filler may be at least one selected from a group consisting of silica (SiO₂), alumina (Al₂O₃), barium sulfate (BaSO₄), talc, mud, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃).

The insulating resin composition may further include 0.1 to 10 parts by weight of a curing agent and 0.01 to 1 part(s) by weight of a curing accelerator, based on 100 parts by weight of the resin composition.

The curing agent may be at least one selected from a group consisting of an amine-based curing agent, an acid anhydride-based curing agent, a polyamine-based curing agent, a polysulfide-based curing agent, a phenol novolac type curing agent, a bisphenol A type curing agent, a dicyandiamide curing agent, and a tetraphenyl olethane curing agent.

The curing accelerator may be at least one selected from a group consisting of a metal-based curing accelerator, an imidazole-based curing accelerator, and an amine based curing accelerator.

The maleimide resin, the liquid crystal oligomer, and the curing agent may have a network structure in which they are connected to each other by a Michael reaction.

The liquid crystal oligomer, the epoxy resin, and the curing agent may have a network structure in which they are connected to each other by a nucleophilic addition.

According to a preferred embodiment of the present invention, there is provided an insulating film prepared by applying and curing the insulating resin composition as described above on a substrate.

According to a preferred embodiment of the present invention, there is provided a prepreg prepared by impregnating a varnish containing the insulating resin composition as described above into an organic fiber or an inorganic fiber and drying the varnish thereon.

According to a preferred embodiment of the present invention, there is provided a printed circuit board manufactured by stacking and laminating the insulating film as described above on a circuit pattern-formed substrate.

According to a preferred embodiment of the present invention, there is provided a multilayer printed circuit board manufactured by laminating an insulating film on a copper clad laminate (CCL) obtained by stacking copper foil on one surface or both surfaces of the prepreg as described above.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a cross-sectional view of a general printed circuit board to which a resin composition according to a preferred embodiment of the present invention is applicable.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

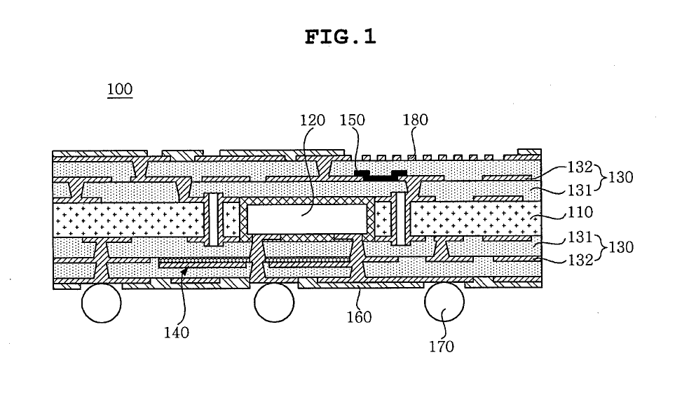

FIG. 1 is a cross-sectional view of a general printed circuit board to which a resin composition according to the present invention is applicable. Referring to FIG. 1, a printed circuit board 100 may be an embedded board into which electronic components are embedded. Specifically, the printed circuit board 100 may include an insulator 110 provided with a cavity, an electronic component 120 disposed in the cavity, and a build up layer 130 disposed on at least one of the upper surface and the lower surface of the insulator 110 including the electronic component 120. The build up layer 130 may include an insulating layer 131 disposed on at least one of the upper surface and the lower surface of the insulator 110, and a circuit layer 132 disposed on the insulating layer 131 and connected between the circuit layer 132 and the insulating layer 131. Herein, an example of the electronic component 120 may be an active element such as a semiconductor element. In addition, the printed circuit board 100 may not include one electronic component 120, but may further include at least one additional electronic component, for example, a capacitor 140 and a resistive element 150, which is not limited to kinds or numbers of the electronic components described in Examples of the present invention. Further, the outermost layer is provided with a solder resist layer 160 for protecting the circuit board. The printed circuit board may be provided with an external connection unit 170 depending on electronic components to be mounted thereon, and may also be provided with a pad layer 180 in some cases. Herein, the insulator 110 and the insulating layer 131 may serve to provide an insulating property between the circuit layers or between the electronic components, and simultaneously serve as a structure to maintain rigidity of a package. In this case, when a wiring density of the printed circuit board 100 is increased, in order to reduce noise between the circuit layers and to simultaneously reduce a parasitic capacitance, the insulator 110 and the insulating layer 131 require a low dielectric constant property. In addition, in order to improve an insulating property, the insulator 110 and the insulating layer 131 require a low dielectric loss property. As described above, at least one of the insulator 110 and the insulating layer 131 should have rigidity, while reducing a dielectric constant and a dielectric loss.

According to the present invention, in order to secure the rigidity of the printed circuit board by decreasing coefficient of thermal expansion of the insulating layer and increasing a glass transition temperature and a storage modulus thereof, the insulating layer 131 and the insulator 110 may be formed of the insulating resin composition for a printed circuit board including the maleimide resin having three or more maleimide groups; the liquid crystal oligomer; and the epoxy resin.

Maleimide Resin

The insulating resin composition according to a preferred embodiment of the present invention may include a maleimide resin having three or more maleimide groups to improve heat resistance of the composition, and for example, preferably include an oligomer of phenyl methane maleimide represented by the following Chemical Formula 1.

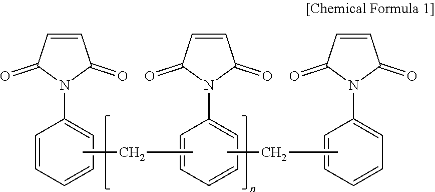

Herein, n is an integer of 1 or 2.

In a case where the insulating resin composition without having an inorganic filler is prepared, an amount of maleimide resin to be used is preferably 10 to 40 wt %. When the amount is less than 10 wt %, there may be no improvement in a glass transition temperature. When the amount is more than 40 wt %, a product may be hardly prepared due to excessive brittleness.

In contrast, in a case where the insulating resin composition with an inorganic filler is prepared, an amount of the maleimide resin to be used is preferably 5 to 20 wt %. When the amount is less than 5 wt %, there may be no improvement in a glass transition temperature. Also, when the amount is more than 20 wt %, a product may be hardly prepared due to excessive brittleness.

Liquid Crystal Oligomer

The liquid crystal oligomer, which is represented by the following Chemical Formula 2 but not limited thereto, may be an oligomer with liquid crystal properties having hydroxyl groups introduced at both ends thereof.

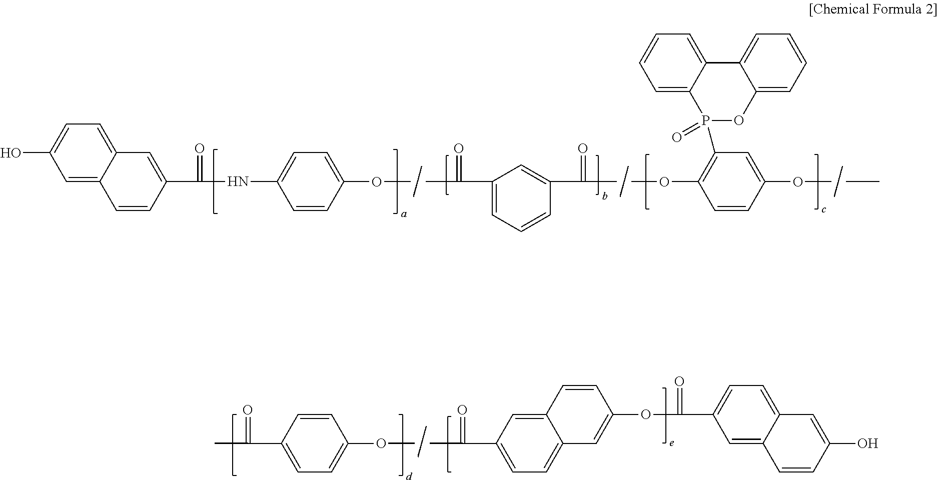

Herein, a is an integer of 13 to 26, b is an integer of 13 to 26, c is an integer of 9 to 21, d is an integer of 10 to 30, and e is an integer of 10 to 30.

In a case where the insulating resin composition without having an inorganic filler is prepared, an amount of liquid crystal oligomer to be used is not specifically limited, but may be preferably 30 to 60 wt %. When the amount is less than 30 wt %, reduction of a coefficient of thermal expansion and improvement of a glass transition temperature may be insignificant. When the amount is more than 60 wt %, mechanical physical properties may be decreased.

In contrast, in a case where the insulating resin composition with an inorganic filler is prepared, an amount of the liquid crystal oligomer to be used is not specifically limited, but may be preferably 10 to 30 wt %. When the amount is less than 10 wt %, reduction of a coefficient of thermal expansion and improvement of a glass transition temperature may be insignificant. When the amount is more than 30 wt %, mechanical physical properties may be decreased.

The number average molecular weight of the liquid crystal oligomer is preferably 2500 to 6500 g/mol, more preferably 3000 to 5500 g/mol, and even more preferably 3500 to 5000 g/mol. When the number average molecular weight is less than 2500 g/mol, mechanical physical properties may be decreased. When the number average molecular weight is more than 6500 g/mol, solubility may be decreased.

Epoxy Resin

The insulating resin composition according to a preferred embodiment of the present invention may include an epoxy resin to improve handling of the dried resin composition as an adhesion film. The epoxy resin refers to an epoxy resin including at least one epoxy functional group in a molecule, preferably at least two epoxy functional groups in a molecule, and more preferably at least four epoxy functional groups in a molecule.

Examples of the epoxy resin to be used for the present invention may include at least one selected from a group consisting of a naphthalene-based epoxy resin, a bisphenol A type epoxy resin, a phenol novolac epoxy resin, a cresol novolac epoxy resin, a rubber modified epoxy resin, a phosphorus-based epoxy resin, and a bisphenol F type epoxy resin, and may preferably include a bisphenol F type epoxy resin represented by the following Chemical Formula 3.

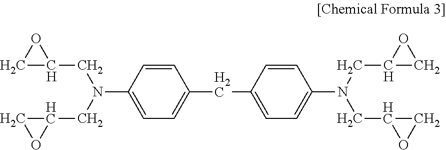 [SMILES: c1cc(N(CC2CO2)CC2CO2)ccc1Cc1ccc(N(CC2CO2)CC2CO2)cc1]

In a case where the insulating resin composition without having an inorganic filler is prepared, an amount of epoxy resin to be used is not specifically limited, but may be preferably 30 to 60 wt %. When the amount is less than 30 wt %, handling may be decreased. When the amount is more than 60 wt %, the relative amount of the other components to be added may be lowered, and thus a dielectric loss tangent, a dielectric constant, and a coefficient of thermal expansion may be hardly improved.

In contrast, in a case where the insulating resin composition with an inorganic filler is prepared, an amount of epoxy resin to be used is not specifically limited, but may be preferably 5 to 20 wt %. When the amount is less than 5 wt %, handling may be decreased. When the amount is more than 20 wt %, the relative amount of other components may be lowered, and thus a dielectric loss tangent, a dielectric constant, and a coefficient of thermal expansion may be hardly improved.

Inorganic Filler

The insulating resin composition according to a preferred embodiment of the present invention may further include an inorganic filler to reduce a coefficient of thermal expansion (CIE) of the epoxy resin. The inorganic filler serves to reduce a coefficient of thermal expansion, and the content of the inorganic filler based on the insulating resin composition may be varied depending on required properties in view of use of the insulating resin composition. The content may be preferably 50 to 80 wt %. When the content is less than 50 wt %, a dielectric loss tangent may be lowered and a coefficient of thermal expansion may be increased. When the content is more than 80 wt %, adhesion strength may be decreased.

The inorganic filler to be used for the present invention may include silica (SiO₂), alumina (Al₂O₃), barium sulfate (BaSO₄), talc, mud, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃) singly or in combination of two or more kinds thereof. Particularly, silica (SiO₂) having a low dielectric loss tangent is preferable.

Curing Agent

According to the present invention, the curing agent may be selectively used. Generally, the curing agent may be used as long as it includes a reaction group capable of reacting with an epoxide ring of the epoxy resin. The curing agent is not specifically limited.

Specific examples of the curing agent may include an amine-based curing agent, an acid anhydride-based curing agent, a polyamine-based curing agent, a polysulfide-based curing agent, a phenol novolac type curing agent, a bisphenol A type curing agent, a dicyandiamide curing agent, and a tetraphenyl olethane curing agent. The curing agent may be used singly or in combination of two or more kinds thereof.

The amount of curing agent to be used may be suitably selected in a range of 0.1 to 10 parts by weight based on 100 parts by weight of the insulating resin composition in view of a curing rate, so as not to decrease intrinsic physical properties of the epoxy resin.

Curing Accelerator

The insulating resin composition according to a preferred embodiment of the present invention may be cured efficiently by selectively adding a curing accelerator thereto. An amount of the curing accelerator to be used for the present invention is not specifically limited, but may be 0.01 to 1 part by weight based on 100 parts by weight of the insulating resin composition. Further, examples of the curing accelerators to be used for the present invention may include a metal-based curing accelerator, an imidazole-based curing accelerator, and an amine-based curing accelerator, and the like. They may be used singly or in combination of two or more kinds thereof.

The metal-based curing accelerator is not specifically limited, but may include organic metal complex or organic metal salt of metal such as cobalt, copper, zinc, iron, nickel, manganese, or tin. Specific examples of the organic metal complex include organic cobalt complex such as cobalt (II) acetylacetonate or cobalt (III) acetylacetonate, organic copper complex such as copper (II) acetylacetonate, organic zinc complex such as zinc (II) acetylacetonate, organic iron complex such as iron (III) acetylacetonate, organic nickel complex such as nickel (II) acetylacetonate, and organic manganese complex such as manganese (II) acetylacetonate. Examples of the organic metal salt include zinc octylate, tin octylate, zinc naphthenate, cobalt naphthenate, tin stearate, zinc stearate, and the like. From the viewpoint of a curing property and solvent solubility, the metal-based curing accelerator may be preferably cobalt (II) acetylacetonate, cobalt (III) acetylacetonate, zinc (II) acetylacetonate, zinc naphthenate, iron (III) acetylacetonate, and more preferably cobalt (II) acetylacetonate or zinc naphthenate. The metal-based curing accelerator may be used singly or in combination of two or more kinds thereof.

Examples of the imidazole-based curing accelerator are not specifically limited, but imidazole compounds such as 2-methyl imidazole, 2-undecyl imidazole, 2-heptadecyl imidazole, 1,2-dimethyl imidazole, 2-ethyl-4-methyl imidazole, 1,2-dimethyl imidazole, 2-ethyl-4-methyl imidazole, 2-phenyl imidazole, 2-phenyl-4-methyl imidazole, 1-benzyl-2-methyl imidazole, 1-benzyl-2-phenyl imidazole, 1-cyanoethyl-2-methyl imidazole, 1-cyanoethyl-2-undecyl imidazole, 1-cyanoethyl-2-ethyl-4-methyl imidazole, 1-cyanoethyl-2-phenyl imidazole, 1-cyanoethyl-2-undecyl imidazolium trimellitate, 1-cyanoethyl-2-phenyl imidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazineisocyanuric acid adduct, 2-phenylimidazol isocyanuric acid adduct, 2-phenyl-4,5-dihydroxylmethylimidazole, 2-phenyl-4-methyl-5-hydroxymethylimidazole, 2,3-dihydroxy-1H-pyrrolo[1,2-a]benzimidazole, 1-dodecyl-2-methyl-3-benzylimidazolium chloride, 2-methyl imidazoline, and 2-phenyl imidazoline, and additives of the imidazole compound, and the epoxy resin. The imidazole curing accelerator may be used singly or in combination of two or more kinds thereof.

Examples of the amine-based curing accelerator are not specifically limited, but trialkyl amine such as triethyl amine or tributyl amine, an amine compound such as 4-dimethylaminopyridine, benzyldimethylamine, 2,4,6-tris(dimethylaminomethyl)phenol, or 1,8-dizabicyclo(5,4,0)-undecene, and the like. The amine-based curing accelerator may be used singly or in combination of two or more kinds.

The maleimide resin, the liquid crystal oligomer, and the curing agent in the insulating resin composition according to a preferred embodiment of the present invention may have a mutually connected network structure by the Michael reaction. Further, the liquid crystal oligomer, the epoxy resin, and the curing agent may have a mutually connected network structure by an nucleophilic addition. Therefore, the maleimide resin having three or more maleimide groups, the liquid crystal oligomer, the epoxy resin, and the curing agent have a mutually connected network, which may exert high heat resistance in the insulating resin composition.

Homo-polymerization of the maleimide resin may be obtained through a curing reaction by radical polymerization, which is represented by the following Reaction Formula 1.

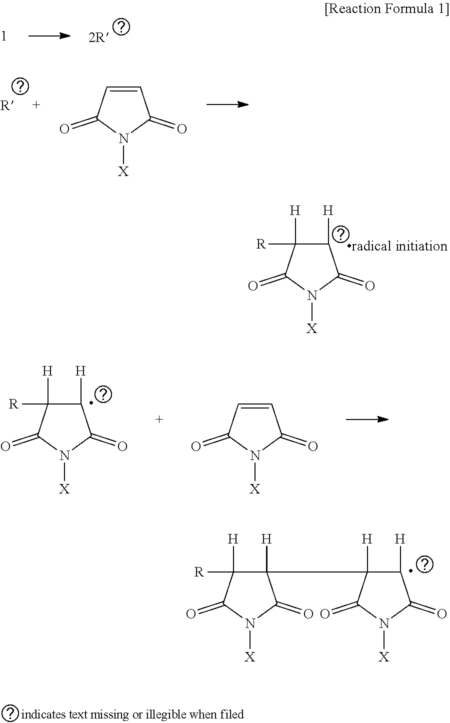

Herein, R is azobisbutyronitrile (AIBN) as a radical initiator, and X is an aromatic phenyl group.

The Michael reaction is a reaction of a double bond of the maleimide resin with a hydroxyl group of the liquid crystal oligomer and an amine group of a dicyandiamide (DICY) as the curing agent, which may be represented by the following Reaction Formulae 2 and 3.

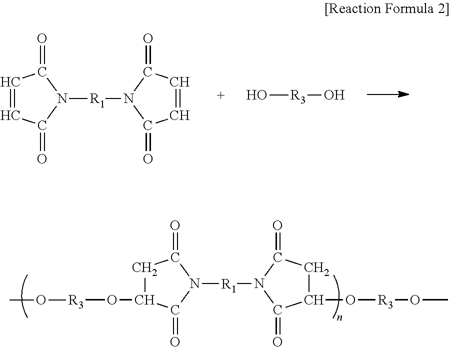

Herein, R₁ is an aromatic phenyl group and R₃ is a structure of the liquid crystal oligomer represented by Chemical Formula 2, except for hydroxyl groups (—OH) at both ends.

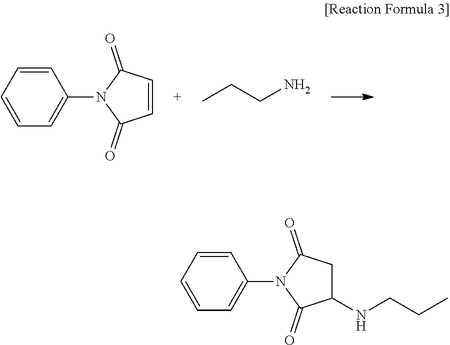

Nucleophilic addition is a reaction of an epoxide group of the epoxy resin with a hydroxyl group of the liquid crystal oligomer and an amine group of a dicyandiamide (DICY) as the curing agent, which may be represented by the following Reaction Formulae 4 and 5.

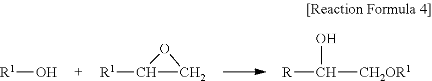

Herein, R is a structure of an N,N,N′,N′-tetraglycidyl-4,4′-methylenebisbenzeneamine epoxy resin having four function groups of Chemical Formula 3 except for one epoxide group, and R¹ is a structure of the liquid crystal oligomer represented by Chemical Formula 2 except for a hydroxyl group (—OH) at both ends.

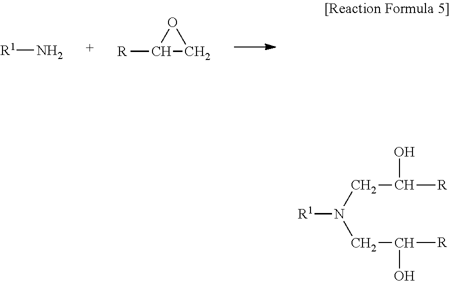

Herein, R is a structure of an N,N,N′,N′-tetraglycidyl-4,4′-methylenebisbenzeneamine epoxy resin having four function groups of Chemical Formula 3 except for one end epoxide group, and R¹ is a structure of a dicyandiamide (DICY) except for an amine group (—NH₂).

The insulating resin composition according to a preferred embodiment of the present invention may be prepared in a semi-solid dry film form, according to general methods known in the art. For example, the composition is formed in the film form by using a roll coater, a curtain coater, or a comma coater, is dried, and then is applied on the board to thereby be used as the insulating layer (or insulating film) or the prepreg upon the preparation of a multilayer printed board by a build-up scheme. The insulating film or the prepreg may improve a glass transition temperature and mechanical strength properties.

As described above, the resin composition according to a preferred embodiment of the present invention is impregnated into a base material such as an organic fiber or an inorganic fiber, and then cured to prepare a prepreg, and a copper foil is stacked on the prepreg to thereby obtain a copper clad laminate (CCL). Further, the insulating film prepared by the resin composition according to a preferred embodiment of the present invention is laminated on a CCL to be used as an inner layer at the time of manufacturing a multilayer printed circuit board, which is used for manufacturing the multilayer printed circuit board. For example, the insulating film prepared by the insulating resin composition is laminated on the inner layer circuit board being processed in a pattern, cured at a temperature of 80 to 110° C. for 20 to 30 minutes, subjected to a desmear process to form a circuit layer through an electric plating process, and thus a multilayer printed circuit board may be prepared.

The inorganic fiber is a glass fiber, and examples of the glass fiber include a carbon fiber, a polyparaphenylene benzobisoxazole fiber, a thermotropic liquid polymer fiber, a lyotropic liquid crystal polymer fiber, an aramide fiber, a polypiridobisimidazole fiber, a polybenzothiazole fiber, and a polyarylate. They may be used singly or in combination of two or more kinds thereof.

The present invention will be described in more detail with reference to Examples and Comparative Examples, but the scope of the present invention is not limited to the following examples.

### PREPARATION EXAMPLE 1

218.26 (2.0 mol) of 4-aminophenol, 415.33 g (2.5 mol) of isophthalic acid, 276.24 g (2.0 mol) of 4-hydroxybenzoic acid, 282.27 g (1.5 mol) of 6-hydroxy-2-naphthoic acid, 648.54 g (2.0 mol) of DOPO-HQ, and 1531.35 g (15.0 mol) of acetic acid anhydride were added to 20 L of a glass reactor. After the inside of the glass reactor was replaced with nitrogen gas, the mixture was refluxed for four hours while the inner temperature of the reactor was increased to 230° C. in nitrogen gas flow and the inner temperature of the reactor was maintained at the same temperature. Subsequently, 188.18 g (1.0 mol) of 6-hydroxy-2-naphthoic acid for capping the end was added thereto, and then acetic acid as a by-product thereof and unreacted acetic acid anhydride were removed to prepare a liquid crystal oligomer.

Preparation of Resin Composition and Insulating Film

### EXAMPLE 1

28.12 g of an N,N′-dimethylacetamide (DMAc) solvent was mixed with 4 g of an oligomer of phenyl methane maleimide and 20 g of the liquid crystal oligomer of Preparation Example 1, and then stirred for about one hour. 16 g of an epoxy resin Araldite MY-721 (Huntsman Corporation) was added thereto, and then stirred for about two hours. Subsequently, 0.16 g of a dicyandiamide (DICY) and 0.1 g of an azobisbutyronitrile (AIBN) were added thereto, and then completely dissolved by stirring for about one hour, to prepare a resin composition. The resin composition was poured suitably on the shiny surface of copper foil, and then an insulating film having a thickness of about 150 μm was obtained with a film caster for laboratory. The insulating film was primarily dried at about 80° C. for 30 minutes in an oven to remove the volatile solvent. Subsequently, the insulating film was secondly dried about 120° C. for 60 minutes to obtain the insulating film in a B-stage state.

### EXAMPLE 2

44.29 g of an N,N′-dimethylacetamide (DMAc) solvent was mixed with 7.5 g of an oligomer of phenyl methane maleimide and 15 g of the liquid crystal oligomer of Preparation Example 1, and then stirred for about one hour. 15 g of an epoxy resin Araldite MY-721 (Huntsman Corporation) was added thereto, and then stirred for about two hours. Subsequently, 0.15 g of a dicyandiamide (DICY) and 0.1875 g of an azobisbutyronitrile (AIBN) were added thereto, and then completely dissolved by stirring for about one hour, to prepare a resin composition. The resin composition was poured suitably on the shiny surface of copper foil, and then an insulating film having a thickness of about 150 μm was obtained with a film caster for laboratory. The insulating film was primarily dried at about 80° C. for 30 minutes in an oven to remove the volatile solvent. Subsequently, the insulating film was secondly dried about 120° C. for 60 minutes to obtain the insulating film in a B-stage state.

### EXAMPLE 3

36.36 g of an N,N′-dimethylacetamide (DMAc) solvent was mixed with 12 g of an oligomer of phenyl methane maleimide and 12 g of the liquid crystal oligomer of Preparation Example 1, and then stirred for about one hour. 16 g of an epoxy resin Araldite MY-721 (Huntsman Corporation) was added thereto, and then stirred for about two hours. Subsequently, 0.16 g of a dicyandiamide (DICY) and 0.3 g of an azobisbutyronitrile (AIBN) were added thereto, and then completely dissolved by stirring for about one hour, to prepare a resin composition. The resin composition was poured suitably on the shiny surface of copper foil, and then an insulating film having a thickness of about 150 μm was obtained with a film caster for laboratory. The insulating film was primarily dried at about 80° C. for 30 minutes in an oven to remove the volatile solvent. Subsequently, the insulating film was secondly dried about 120° C. for 60 minutes to obtain the insulating film in a B-stage state.

### EXAMPLE 4

32.51 g of an N,N′-dimethylacetamide (DMAc) solvent was mixed with 12 g of an oligomer of phenyl methane maleimide and 6 g of the liquid crystal oligomer of Preparation Example 1, and then stirred for about one hour. 12 g of an epoxy resin Araldite MY-721 (Huntsman Corporation) was added thereto, and then stirred for about two hours. Subsequently, 0.12 g of a dicyandiamide (DICY) and 0.3 g of an azobisbutyronitrile (AIBN) were added thereto, and then completely dissolved by stirring for about one hour, to prepare a resin composition. The resin composition was poured suitably on the shiny surface of copper foil, and then an insulating film having a thickness of about 150 μm was obtained with a film caster for laboratory. The insulating film was primarily dried at about 80° C. for 30 minutes in an oven to remove the volatile solvent. Subsequently, the insulating film was secondly dried about 120° C. for 60 minutes to obtain the insulating film in a B-stage state.

### COMPARATIVE EXAMPLE 1

24 g of an N,N′-dimethylacetamide (DMAc) solvent was added to 24 g of the liquid crystal oligomer of Preparation Example 1, and then stirred for about one hour. 16 g of an epoxy resin Araldite MY-721 (Huntsman Corporation) was added thereto, and then stirred for about two hours. Subsequently, 0.16 g of a dicyandiamide (DICY), and then completely dissolved by stirring for about one hour, to prepare a resin composition. The resin composition was poured suitably on the shiny surface of copper foil, and then an insulating film having a thickness of about 150 μm was obtained with a film caster for laboratory. The insulating film was primarily dried at about 80° C. for 30 minutes in an oven to remove the volatile solvent. Subsequently, the insulating film was secondly dried about 120° C. for 60 minutes to obtain the insulating film in a B-stage state.

A glass transition temperature (Tg) of the insulating film prepared in Examples 1 to 4 and Comparative Example 1 was measured using a DSC equipment of TA company, and 5 mg of each of the prepared insulating films was injected into the DSC equipment, primarily measured up to 300° C. by 10° C. per minute, and then cooled; and thereafter, secondly measured up to 300° C. by 10° C. per minute, and a glass transition temperature (Tg) was measured based on the secondly measured value.

TABLE 1

| Classification | Glass transition temperature (Tg) (° C.) |
|---|---|
| Example 1 | 215 |
| Example 2 | 218 |
| Example 3 | 240 |
| Example 4 | 240 |
| Comparative | 210 |
| Example 1 | |

As can be appreciated from Table 1, it can be confirmed a glass transition temperature of each of Examples 1 to 4 is relatively better than that of Comparative Example 1 without having an oligomer of phenyl methane maleimide. Also, it can be appreciated that a glass transition temperature increases as the content of the oligomer of phenyl methane maleimide increases.

Preparation of Prepreg

### EXAMPLE 5

43.12 g of an N,N′-dimethylacetamide (DMAc) solvent was mixed with 4 g of an oligomer of phenyl methane maleimide, 20 g of the liquid crystal oligomer of Preparation Example 1, and 60 g of a silica (SiO₂) slurry, and then stirred for about one hour. 16 g of an epoxy resin Araldite MY-721 (Huntsman Corporation) was added thereto, and then stirred for about two hours. Subsequently, 0.16 g of a dicyandiamide (DICY) and 0.1 g of an azobisbutyronitrile (AIBN) were added thereto, and then completely dissolved by stirring for about one hour, to prepare a resin composition. After completion of stirring, a varnish containing the resin composition was impregnated into an organic fiber or an inorganic fiber, put on an oven, and then dried at about 120° C. for 15 minutes. After completion of drying, the resultant was heated to 220° C. and completely cured while being maintained for about 90 minutes at a pressure of 30 kgf/cm² at a temperature of 220° C. to prepare a prepreg.

### EXAMPLE 6

44.29 g of an N,N′-dimethylacetamide (DMAc) solvent was mixed with 7.5 g of an oligomer of phenyl methane maleimide, 15 g of the liquid crystal oligomer of Preparation Example 1, and 56.24 g of a silica (SiO₂) slurry, and then stirred for about one hour. 15 g of an epoxy resin Araldite MY-721 (Huntsman Corporation) was added thereto, and then stirred for about two hours. Subsequently, 0.15 g of a dicyandiamide (DICY) and 0.1875 g of an azobisbutyronitrile (AIBN) were added thereto, and then completely dissolved by stirring for about one hour, to prepare a resin composition. After completion of stirring, a varnish containing the resin composition was impregnated into an organic fiber or an inorganic fiber, put on an oven, and then dried for 15 minutes at about 120° C. After completion of drying, the resultant was heated to 220° C. and completely cured while being maintained for about 90 minutes at a pressure of 30 kgf/cm² at a temperature of 220° C. to prepare a prepreg.

### EXAMPLE 7

51.36 g of an N,N′-dimethylacetamide (DMAc) solvent was mixed with 12 g of an oligomer of phenyl methane maleimide, 12 g of the liquid crystal oligomer of Preparation Example 1, and 60 g of a silica (SiO₂) slurry, and then stirred for about one hour. 16 g of an epoxy resin Araldite MY-721 (Huntsman Corporation) was added thereto, and then stirred for about two hours. Subsequently, 0.16 g of a dicyandiamide (DICY) and 0.3 g of an azobisbutyronitrile (AIBN) were added thereto, and then completely dissolved by stirring for about one hour, to prepare a resin composition. After completion of stirring, a varnish containing the resin composition was impregnated into an organic fiber or an inorganic fiber, put on an oven, and then dried at about 120° C. for 15 minutes. After completion of drying, the resultant was heated to 220° C. and completely cured while being maintained for about 90 minutes at a pressure of 30 kgf/cm² at a temperature of 220° C. to prepare a prepreg.

### EXAMPLE 8

41.51 g of an N,N′-dimethylacetamide (DMAc) solvent was mixed with 12 g of an oligomer of phenyl methane maleimide, 6 g of the liquid crystal oligomer of Preparation Example 1, and 45 g of a silica (SiO₂) slurry, and then stirred for about one hour. 12 g of an epoxy resin Araldite MY-721 (Huntsman Corporation) was added thereto, and then stirred for about two hours. Subsequently, 0.12 g of a dicyandiamide (DICY) and 0.3 g of an azobisbutyronitrile (AIBN) were added thereto, and then completely dissolved by stirring for about one hour, to prepare a resin composition. After completion of stirring, a varnish containing the resin composition was impregnated into an organic fiber or an inorganic fiber, put on an oven, and then dried for 15 minutes at about 120° C. After completion of drying, the resultant was heated to 220° C. and completely cured while being maintained for about 90 minutes at a pressure of 30 kgf/cm² at a temperature of 220° C. to prepare a prepreg.

### COMPARATIVE EXAMPLE 2

39 g of an N,N′-dimethylacetamide (DMAc) solvent was mixed with 24 g of the liquid crystal oligomer of Preparation Example 1 and 60 g of a silica (SiO₂) slurry, and then stirred for about one hour. 16 g of an epoxy resin Araldite MY-721 (Huntsman Corporation) was added thereto, and then stirred for about two hours. Subsequently, 0.16 g of a dicyandiamide (DICY), and then completely dissolved by stirring for about one hour, to prepare a resin composition. After completion of stirring, a varnish containing the resin composition was impregnated into an organic fiber or an inorganic fiber, put on an oven, and then dried for 15 minutes at about 120° C. After completion of drying, the resultant was heated to 220° C. and completely cured while being maintained for about 90 minutes at a pressure of 30 kgf/cm² at a temperature of 220° C. to prepare a prepreg.

A mechanical modulus of each of the prepregs prepared through Examples 5 to 8 and Comparative Example 2 was measured using a dynamic analyzer (DMA), and storage modulus at 250° C. was measured.

TABLE 2

| | storage modulus |
|---|---|
| Classification | (GPa) |
| Example 5 | 20 |
| Example 6 | 19 |
| Example 7 | 22 |
| Example 8 | 22 |
| Comparative Example 2 | 18 |

As can be appreciated from Table 2, it can be confirmed that a storage modulus of each of Examples 5 to 8 is relatively better than that of Comparative Example 2 without having an oligomer of phenyl methane maleimide. Further, in Examples 5 to 8, it can be believed that a mechanical modulus increases as the content of the oligomer of phenyl methane maleimide increases.

Manufacturing of Printed Circuit Board

### EXAMPLE 9

Copper foil layers were stacked onto both surfaces of the prepreg prepared by Example 8 to form a circuit pattern. Subsequently, the formed circuit pattern was dried for 30 minutes at a temperature condition of about 120° C. and the insulating film prepared by Example 4 was stacked onto the circuit pattern-formed substrate, and vacuum-laminated for 20 seconds at the condition of about 90° C., 20 MPa using a Morton CVA 725 vacuum laminate to manufacture a printed circuit board.

As set forth above, according to the preferred embodiments of the present invention, the insulating film, the prepreg, and the printed circuit board, prepared by using the insulating resin composition including the maleimide resin having three or more maleimide groups can have a good glass transition temperature and mechanical strength properties.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

1. An insulating resin composition for a printed circuit board comprising:
a maleimide resin having three or more maleimide groups;
a liquid crystal oligomer; and
an epoxy resin.

2. The insulating resin composition for a printed circuit board as set forth in claim 1, further comprising an inorganic filler.

3. The insulating resin composition for a printed circuit board as set forth in claim 1, wherein a content of the maleimide resin is 10 to 40 wt %, a content of the liquid crystal oligomer is 30 to 60 wt %, and a content of the epoxy resin is 30 to 60 wt %, based on 100 parts by weight of the resin composition.

4. The insulating resin composition for a printed circuit board as set forth in claim 2, wherein a content of the maleimide resin is 5 to 20 wt %, a content of the liquid crystal oligomer is 10 to 30 wt %, and a content of the inorganic filler is 50 to 80 wt %, based on 100 parts by weight of the resin composition.

5. The insulating resin composition for a printed circuit board as set forth in claim 1, wherein the maleimide resin is an oligomer of phenyl methane maleimide represented by the following Chemical Formula 1: 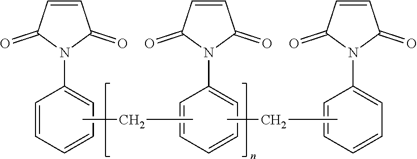
wherein, n is an integer of 1 or 2.

6. The insulating resin composition for a printed circuit board as set forth in claim 1, wherein the liquid crystal oligomer is represented by the following Formula 2: 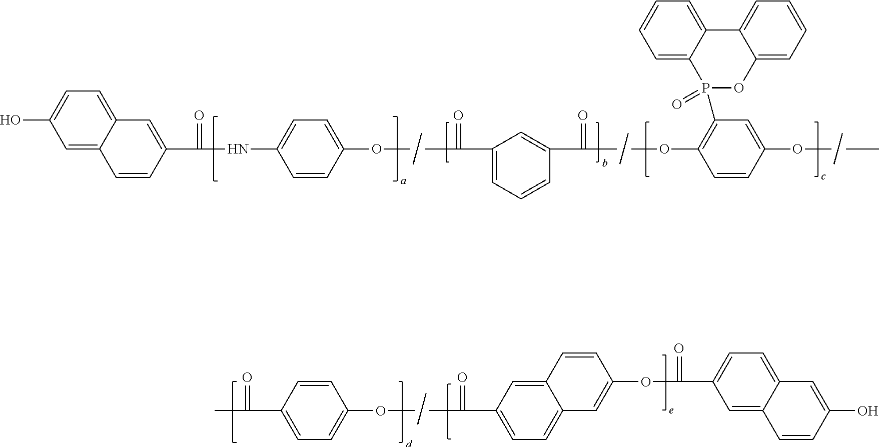
wherein, a is an integer of 13 to 26, b is an integer of 13 to 26, c is an integer of 9 to 21, d is an integer of 10 to 30, and e is an integer of 10 to 30.

7. The insulating resin composition for a printed circuit board as set forth in claim 1, wherein the epoxy resin is at least one selected from a group consisting of a naphthalene-based epoxy resin, a bisphenol A type epoxy resin, a phenol novolac epoxy resin, a cresol novolac epoxy resin, a rubber modified epoxy resin, a phosphorus-based epoxy resin, and a bisphenol F type epoxy resin.

8. The insulating resin composition for a printed circuit board as set forth in claim 2, wherein the inorganic filler is at least one selected from a group consisting of silica (SiO₂), alumina (Al₂O₃), barium sulfate (BaSO₄), talc, mud, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃).

9. The insulating resin composition for a printed circuit board as set forth in claim 1, further comprising 0.1 to 10 parts by weight of a curing agent and 0.01 to 1 part(s) by weight of a curing accelerator, based on 100 parts by weight of the resin composition.

10. The insulating resin composition for a printed circuit board as set forth in claim 9, wherein the curing agent is at least one selected from a group consisting of an amine-based curing agent, an acid anhydride-based curing agent, a polyamine-based curing agent, a polysulfide-based curing agent, a phenol novolac type curing agent, a bisphenol A type curing agent, a dicyandiamide curing agent, and a tetraphenyl olethane curing agent.

11. The insulating resin composition for a printed circuit board as set forth in claim 9, wherein the curing accelerator is at least one selected from a group consisting of a metal-based curing accelerator, an imidazole-based curing accelerator, and an amine based curing accelerator.

12. The insulating resin composition for a printed circuit board as set forth in claim 9, wherein the maleimide resin, the liquid crystal oligomer, and the curing agent have a network structure in which they are connected to each other by a Michael reaction.

13. The insulating resin composition for a printed circuit board as set forth in claim 9, wherein the liquid crystal oligomer, the epoxy resin, and the curing agent have a network structure in which they are connected to each other by a nucleophilic addition.

14. An insulating film prepared by applying and curing the insulating resin composition as set forth in claim 1 on a substrate.

15. A prepreg prepared by impregnating a varnish containing the insulating resin composition as set forth in claim 1 into an organic fiber or an inorganic fiber and drying the varnish thereon.

16. A printed circuit board manufactured by stacking and laminating the insulating film as set forth in claim 14 on a circuit pattern-formed substrate.

17. A multilayer printed circuit board manufactured by laminating an insulating film on a copper clad laminate (CCL) obtained by stacking copper foil on one surface or both surfaces of the prepreg as set forth in claim 15.
